(19) United States
(12) Patent Application Publication
(10) Pub. No.: US 2026/0153323 A1
(43) Pub. Date: Jun. 4, 2026

(54) ZERO-ORDER OVERLAY METROLOGY

(71) Applicant: KLA Corporation, Milpitas, CA (US)

(72) Inventors: Amnon Manassen, Haifa (IL); Vladimir Levinski, Migdal HaEmek (IL)

(21) Appl. No.: 18/968,687

(22) Filed: Dec. 4, 2024

(51) Int. Cl. G01B 9/02001; G01B 9/02; G02B 5/30; G03F 7/00

(52) U.S. Cl. CPC G01B 9/02007; G01B 9/02034; G02B 5/3025; G03F 7/70633; G01B 2210/56

(57) ABSTRACT

A metrology system may include an illumination source to generate one or more illumination beams, a detector, and an imaging sub-system including one or more lenses to image a sample onto the detector, where the sample includes overlapping periodic features on two sample layers. The imaging sub-system may image the overlapping periodic features using zero-order double diffraction of the one or more illumination beams by the overlapping periodic features. The system may further include a controller to receive an image of the overlapping periodic features from the detector based on the zero-order double diffraction of the one or more illumination beams by the overlapping periodic features, and generate metrology measurements of the sample based on the image. Constituent features of the overlapping periodic features may be unresolved in the image, but the metrology measurements may be spatially resolved across the image.

### TECHNICAL FIELD

The present disclosure relates generally to overlay metrology and, more particularly, to overlay metrology using zero-order diffraction from overlapping periodic features.

### BACKGROUND

Metrology during semiconductor fabrication is a critical enabler for decreasing the size of device features. Advancements of semiconductor nodes have necessitated tighter measurement tolerances such that localized variations across a device (e.g., localized variations within a cell of a memory device) may be significant enough to impact yield. In some applications, >7σ errors may impact yield. There is therefore a need to develop systems and methods providing overlay measurements with spatial resolutions sufficient to characterize inter-cell variations.

### SUMMARY

In embodiments, the techniques described herein relate to a metrology system including an illumination source configured to generate one or more illumination beams; an imaging sub-system including one or more lenses configured to image a sample onto a detector located in a field plane conjugate to the sample, where the sample includes overlapping periodic features on two sample layers, where the overlapping periodic features on the two sample layers have a common pitch, where the detector generates zero-order double diffraction signals associated with zero-order double diffraction of the one or more illumination beams by the overlapping periodic features; and one or more ellipsometry optics including at least one of a polarizer or a waveplate in an optical path associated with at least one of the one or more illumination beams or the zero-order double diffraction; and a controller including one or more processors configured to execute program instructions causing the one or more processors to implement a metrology recipe by receiving the zero-order double diffraction signals associated with the overlapping periodic features from the detector and generated with one or more configurations of the one or more ellipsometry optics, where constituent features of the overlapping periodic features are unresolved in the zero-order double diffraction signals; and generating one or more spatially-resolved metrology measurements of the sample based on spatial variations of the zero-order double diffraction signals generated with the one or more configurations of the one or more ellipsometry optics.

In embodiments, the techniques described herein relate to a metrology system, where the zero-order double diffraction corresponds to double near-field diffraction from the overlapping periodic features.

In embodiments, the techniques described herein relate to a metrology system, where the one or more spatially-resolved metrology measurements include at least one of an overlay measurement, an asymmetry measurement, or a critical dimension measurement.

In embodiments, the techniques described herein relate to a metrology system, where the one or more spatially-resolved metrology measurements correspond to spatially-resolved measurements of one or more Mueller matrix elements.

In embodiments, the techniques described herein relate to a metrology system, where the one or more illumination beams from the illumination source include two temporally coherent illumination beams, where the imaging sub-system directs the two temporally coherent illumination beams to the overlapping periodic features at opposing azimuth incidence angles, where the imaging sub-system images the overlapping periodic features on the detector based on interference between the zero-order double diffraction of the two temporally coherent illumination beams.

In embodiments, the techniques described herein relate to a metrology system, where generating the one or more spatially-resolved metrology measurements of the sample based on the zero-order double diffraction signals includes generating the one or more spatially-resolved metrology measurements based on an amplitude of sinusoidal variations in the zero-order double diffraction signals associated with interference of the zero-order double diffraction of the two temporally coherent illumination beams.

In embodiments, the techniques described herein relate to a metrology system, where the one or more spatially-resolved metrology measurements include an overlay measurement.

In embodiments, the techniques described herein relate to a metrology system, where the overlapping periodic features include first-layer features and second-layer features, where the first-layer features and the second-layer features have the common pitch, where the first-layer features and the second-layer features have a designed overlay offset equal to a quarter of the common pitch.

In embodiments, the techniques described herein relate to a metrology system, where the one or more illumination beams from the illumination source include a single illumination beam.

In embodiments, the techniques described herein relate to a metrology system, where generating the one or more spatially-resolved metrology measurements of the sample based on the zero-order double diffraction signals includes generating the one or more spatially-resolved metrology measurements of the sample based on spatial variations of the zero-order double diffraction signals.

In embodiments, the techniques described herein relate to a metrology system, where the zero-order double diffraction signals associated with the overlapping periodic features from the detector and generated with one or more configurations of the one or more ellipsometry optics include two or more sets of zero-order double diffraction signals generated with different wavelengths of the single illumination beam, where the single illumination beam illuminates a region of interest of the overlapping periodic features.

In embodiments, the techniques described herein relate to a metrology system, where the single illumination beam is shaped as a slit having dimensions smaller than a region of interest of the overlapping periodic features, where the zero-order double diffraction signals associated with the overlapping periodic features from the detector and generated with one or more configurations of the one or more ellipsometry optics include two or more sets of zero-order double diffraction signals generated with different positions of the slit across region of interest.

In embodiments, the techniques described herein relate to a metrology system, where the overlapping periodic features include device features within a die on the sample.

In embodiments, the techniques described herein relate to a metrology system, where the overlapping periodic features are associated with at least one of a memory device or a logic device.

In embodiments, the techniques described herein relate to a metrology system, where the overlapping periodic features are associated with a metrology target.

In embodiments, the techniques described herein relate to a metrology system, where the program instructions further cause the one or more processors to generate correctables for one or more fabrication tools based on the one or more spatially-resolved metrology measurements.

In embodiments, the techniques described herein relate to a metrology system including a controller including one or more processors configured to execute program instructions causing the one or more processors to implement a metrology recipe by receiving zero-order double diffraction signals associated with overlapping periodic features on two sample layers of a sample from a detector, where the overlapping periodic features on the two sample layers have a common pitch, where the zero-order double diffraction signals are based on zero-order double diffraction of one or more illumination beams by the overlapping periodic features, where the zero-order double diffraction signals are associated with one or more configurations of ellipsometry optics including at least one of a polarizer or a waveplate in an optical path associated with at least one of the one or more illumination beams or the zero-order double diffraction; and generating one or more spatially-resolved metrology measurements of the sample based on the zero-order double diffraction signals.

In embodiments, the techniques described herein relate to a metrology system, where the zero-order double diffraction corresponds to double near-field diffraction from the overlapping periodic features.

In embodiments, the techniques described herein relate to a metrology system, where the one or more spatially-resolved metrology measurements include at least one of an overlay measurement, an asymmetry measurement, or a critical dimension measurement.

In embodiments, the techniques described herein relate to a metrology system, where the one or more spatially-resolved metrology measurements correspond to spatially-resolved measurements of one or more Mueller matrix elements.

In embodiments, the techniques described herein relate to a metrology system, where the one or more illumination beams include two temporally coherent illumination beams, where the two temporally coherent illumination beams are directed to the overlapping periodic features at opposing azimuth incidence angles, where the zero-order double diffraction signals are based on interference between the zero-order double diffraction of the two temporally coherent illumination beams.

In embodiments, the techniques described herein relate to a metrology system, where generating the one or more spatially-resolved metrology measurements of the sample based on the zero-order double diffraction signals includes generating the one or more spatially-resolved metrology measurements based on an amplitude of sinusoidal variations in the zero-order double diffraction signals associated with the interference of the zero-order double diffraction of the two temporally coherent illumination beams.

In embodiments, the techniques described herein relate to a metrology system, where the one or more spatially-resolved metrology measurements include an overlay measurement.

In embodiments, the techniques described herein relate to a metrology system, where the overlapping periodic features include first-layer features and second-layer features, where the first-layer features and the second-layer features have the common pitch, where the first-layer features and the second-layer features have a designed overlay offset equal to a quarter of the common pitch.

In embodiments, the techniques described herein relate to a metrology system, where the one or more illumination beams include a single illumination beam.

In embodiments, the techniques described herein relate to a metrology system, where generating the one or more spatially-resolved metrology measurements of the sample based on the zero-order double diffraction signals includes generating the one or more spatially-resolved metrology measurements of the sample based on intensity in the zero-order double diffraction signals.

In embodiments, the techniques described herein relate to a metrology system, where the zero-order double diffraction signals associated with the overlapping periodic features from the detector and generated with one or more configurations of the one or more ellipsometry optics include two or more sets of zero-order double diffraction signals generated with different wavelengths of the single illumination beam, where the single illumination beam illuminates a region of interest of the overlapping periodic features.

In embodiments, the techniques described herein relate to a metrology system, where the single illumination beam is shaped as a slit having dimensions smaller than a region of interest of the overlapping periodic features, where the zero-order double diffraction signals associated with the overlapping periodic features from the detector and generated with one or more configurations of the one or more ellipsometry optics include two or more sets of zero-order double diffraction signals generated with different positions of the slit across region of interest.

In embodiments, the techniques described herein relate to a metrology system, where generating the one or more spatially-resolved metrology measurements of the sample based on the zero-order double diffraction signals includes generating the one or more spatially-resolved metrology measurements of the sample based on spatial variations of intensity in the zero-order double diffraction signals.

In embodiments, the techniques described herein relate to a metrology system, where the overlapping periodic features include device features within a die on the sample.

In embodiments, the techniques described herein relate to a metrology system, where the overlapping periodic features are associated with at least one of a memory device or a logic device.

In embodiments, the techniques described herein relate to a metrology system, where the overlapping periodic features are associated with a metrology target.

In embodiments, the techniques described herein relate to a metrology system, where the program instructions further cause the one or more processors to generate correctables for one or more fabrication tools based on the one or more spatially-resolved metrology measurements.

In embodiments, the techniques described herein relate to a metrology system including generating zero-order double diffraction signals associated with overlapping periodic features on two sample layers of a sample based on zero-order double diffraction of one or more illumination beams by the overlapping periodic features, where the overlapping periodic features on the two sample layers have a common pitch, where the zero-order double diffraction signals are associated with one or more configurations of ellipsometry optics including at least one of a polarizer or a waveplate in an optical path associated with at least one of the one or more illumination beams or the zero-order double diffraction; and generating one or more spatially-resolved metrology measurements of the sample based on the zero-order double diffraction signals.

In embodiments, the techniques described herein relate to a metrology system, where generating the one or more spatially-resolved metrology measurements of the sample based on the zero-order double diffraction signals includes generating the one or more spatially-resolved metrology measurements of the overlapping periodic features.

In embodiments, the techniques described herein relate to a metrology system, where generating the one or more spatially-resolved metrology measurements of the sample based on the zero-order double diffraction signals includes generating at least one of an overlay measurement, an asymmetry measurement, or a critical dimension measurement.

In embodiments, the techniques described herein relate to a metrology system, where generating the one or more spatially-resolved metrology measurements of the sample based on the zero-order double diffraction signals includes generating a measurement of at least one Mueller matrix element.

In embodiments, the techniques described herein relate to a metrology system, where the one or more illumination beams include two temporally coherent illumination beams, where generating the zero-order double diffraction signals associated with the overlapping periodic features on the two sample layers of the sample based on the zero-order double diffraction of the one or more illumination beams by the overlapping periodic features includes directing the two temporally coherent illumination beams to the overlapping periodic features at opposing azimuth incidence angles; and imaging the overlapping periodic features based on interference between the zero-order double diffraction of the two temporally coherent illumination beams.

In embodiments, the techniques described herein relate to a metrology system, further including generating one or more correctables for a fabrication tool based on the one or more spatially-resolved metrology measurements.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a block diagram of a metrology system, in accordance with one or more embodiments of the present disclosure.

FIG. 1B illustrates a simplified schematic of an imaging sub-system, in accordance with one or more embodiments of the present disclosure.

FIG. 1C illustrates a simplified schematic view of a configuration of an imaging sub-system providing imaging based on zero-order light from a pair of mutually-coherent illumination beams, in accordance with one or more embodiments of the present disclosure.

FIG. 1D illustrates a simplified schematic view of a first configuration of the imaging sub-system providing imaging based on zero-order light from a single illumination beam, in accordance with one or more embodiments of the present disclosure.

FIG. 1E illustrates a simplified schematic view of a first configuration of the imaging sub-system providing imaging based on zero-order light from a single illumination beam, in accordance with one or more embodiments of the present disclosure.

FIG. 2 illustrates the coding of metrology information into zero-order double-diffraction from overlapping periodic features, in accordance with one or more embodiments of the present disclosure.

FIG. 3A illustrates two mutually-coherent illumination beams at opposing portions of an illumination pupil, in accordance with one or more embodiments of the present disclosure.

FIG. 3B illustrates a collection pupil depicting zero-order double diffraction from overlapping periodic features associated with a pair of mutually-coherent illumination beams oriented as shown in FIG. 3A, in accordance with one or more embodiments of the present disclosure.

FIG. 3C illustrates an image of overlapping periodic features generated based on the collected zero-order double diffraction, where the image includes interference fringes, in accordance with one or more embodiments of the present disclosure.

FIG. 4 illustrates a flow diagram illustrating steps performed in a metrology method 400, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing spatially-resolved metrology measurements of overlapping periodic features within a measurement field (e.g., within an illumination spot size) of an optical metrology tool. In embodiments, a portion of a sample including overlapping periodic features (e.g., grating-over-grating features) is imaged based on zero-order double diffraction from the overlapping periodic features and one or more metrology measurements are generated based on zero-order double diffraction signals associated with the overlapping periodic signals. In some embodiments, the overlapping periodic features are not resolvable in an image of the sample. However, zero-order double diffraction signals associated with the overlapping periodic features may be manifested as intensity signals in an image of the sample. Further, these zero-order double diffraction signals may vary spatially in an image, which may provide spatial resolution for metrology measurements based on these zero-order double diffraction signals.

As used herein, zero-order double diffraction refers to light that interacts with overlapping periodic features through double diffraction of evanescent waves and emanates from the features at a reflection angle. It is contemplated herein that such zero-order double diffraction may include “coded” phase information associated with the overlapping periodic features, even if the features themselves are not resolved by the optical system. Further, zero-order double diffraction signals refers to signals generated by a detector associated with portions of an image associated with overlapping periodic structures of interest. As a result, various spatially-resolved metrology measurements may be extracted from zero-order double diffraction signals including, but not limited to, overlay measurements, asymmetry measurements (e.g., tilt measurements, or the like), or critical dimension (CD) measurements.

In some embodiments, overlapping periodic features on a sample are imaged based on an interference of zero-order double diffraction from two temporally coherent illumination beams incident on the sample from opposing azimuth incidence angles. Such a configuration may generate an interference pattern on a detector at a field plane (e.g., an imaging detector), where a local amplitude of the interference pattern at the detector relates to a local value of a measured parameter. Further, a measurement system may include polarizers and/or waveplates to control the polarization and phase of any combination of the illumination beams and the sample light used for image formation, which may be used to tune a sensitivity of a measurement to different features of interest in a manner similar to ellipsometry measurements (e.g., spectral ellipsometry measurements, or the like). For example, different sample properties of interest (e.g., overlay, asymmetry, CD, or the like) may have different sensitivities to properties of zero-order double diffraction such as, but not limited to, polarization, phase, or wavelength of the illumination beams and collected sample light.

Metrology based on illumination of a sample with mutually-coherent pairs of illumination beams is generally described in U.S. Pat. No. 12,032,300 issued on Jul. 9, 2024, which is incorporated herein by reference in its entirety.

Further, the systems and methods disclosed herein may be suitable for, but not limited to, metrology measurements on any portion of a sample having overlapping periodic features sufficiently close together (e.g., in a depth direction) to produce zero-order double diffraction. In some embodiments, the systems and methods disclosed herein are used to generate metrology measurements of device features (e.g., features in a die on the sample) that naturally include overlapping periodic features such as, but not limited to, memory features (e.g., DRAM cells, SRAM cells, or the like) or logic features. In some embodiments, the systems and methods disclosed herein are used to generate metrology measurements of dedicated metrology targets.

In some embodiments, the systems and methods disclosed herein are used to provide after etch inspection (AEI) measurements. It is contemplated herein that AEI measurements may often provide a high correlation to yield, but that existing techniques for AEI measurements typically suffer from either slow measurement speeds or insufficient spatial resolution. For example, AEI measurements of device-pitch features may be carried out by a scanning electron microscope (SEM), which provides high spatial resolution but slow measurement speeds. As another example, AEI measurements of device-pitch features may be carried out by a spectroscopic ellipsometer (SE), which provides faster measurements but is typically limited to a resolution of around 20 μm. However, this resolution may be insufficient to characterize localized metrology variations that impact yield for advanced nodes.

However, the systems and methods disclosed herein may provide both high spatial resolution and measurement speed. As a result, the systems and methods disclosed herein may provide accurate AEI measurements directly on suitable device features or dedicated metrology targets. In some cases, these AEI measurements may be used directly in a high-volume manufacturing process. In some cases, these AEI measurements may be used to calibrate after development inspection (ADI) measurements. For example, AEI measurements are routinely used to calibrate for a difference between an AEI measurement and an ADI measurement with a different metrology tool more suitable for high-volume measurements, where this difference is commonly referred to as non-zero offset (NZO) or mis-reading correction (MRC).

In some embodiments, the spatially-resolved metrology measurements are used to generate correctables to control one or more additional process tools such as, but not limited to, a lithography tool, an etching tool, or a polishing tool.

In some embodiments, the spatially-resolved metrology measurements are used to calibrate overlay, asymmetry, or other field distribution signals using data associated with Scanning Electron Microscopy (SEM), self-calibration targets, Design of Experiments (DOE), various models, or the like.

It is contemplated that the systems and methods disclosed herein may enable the measurement of overlay or other metrology measurements in a deeply under-resolved structure. The systems and methods disclosed herein employ mutually coherent zero-order scattered beams for image formation, allowing for the extraction of overlay, asymmetry, and other information that is “coded” within the zero-order beams and manifested at the field plane. By analyzing a generated interference signal (e.g., present in an image), the field distribution of overlay, asymmetry, and other information can be accurately measured. Moreover, the systems and methods disclosed herein may optimize wavelength, angles, and polarization states to maximize sensitivity to the overlay, asymmetry, and other information present in the generated interference signal.

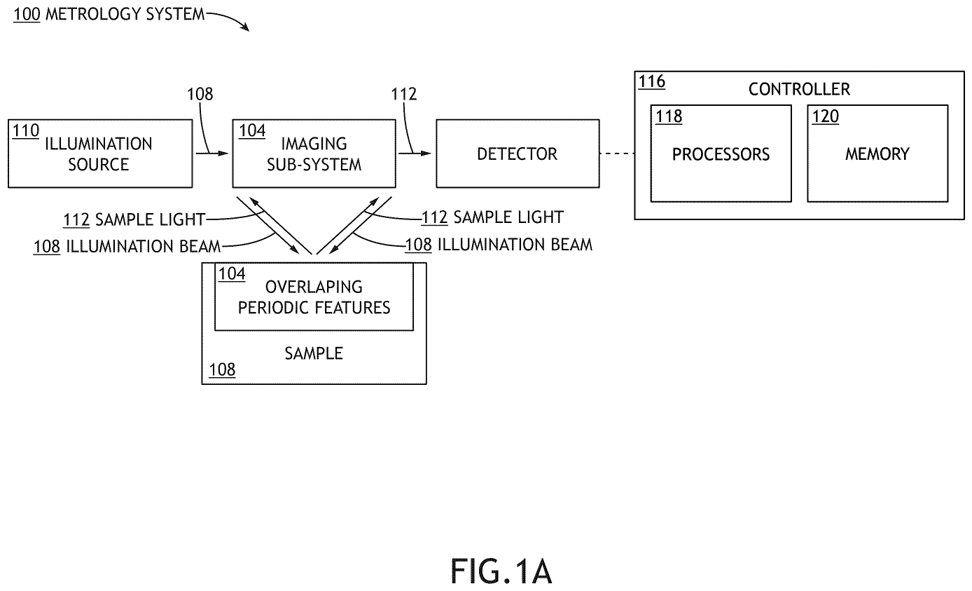

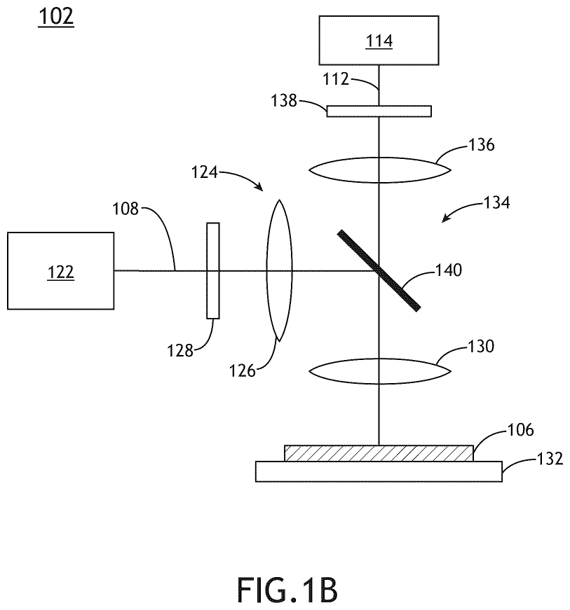

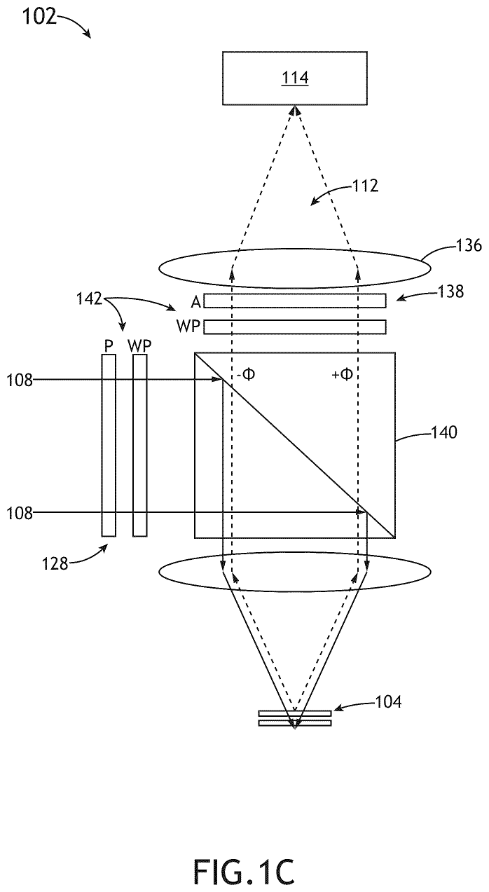

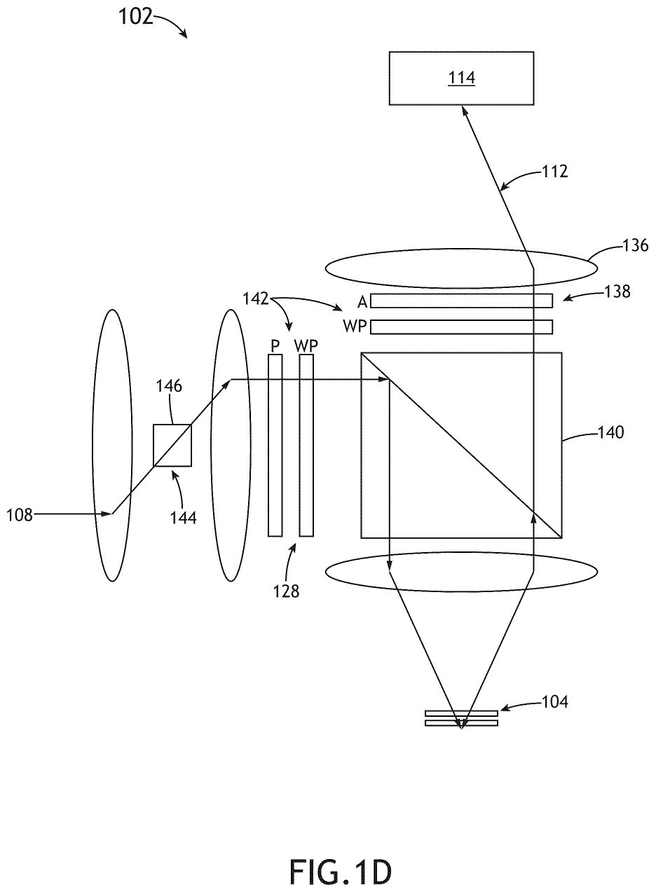

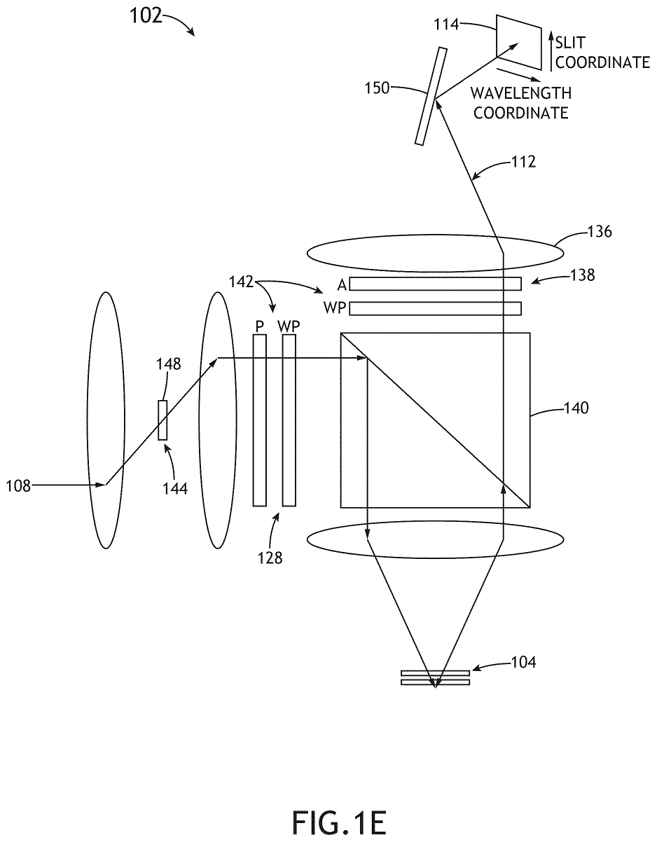

Referring now to FIGS. 1A-4, systems and methods providing spatially-resolved metrology measurements of overlapping periodic features based on imaging with zero-order diffraction signals is described in greater detail, in accordance with one or more embodiments of the present disclosure.

FIG. 1A illustrates a block diagram of a metrology system 100, in accordance with one or more embodiments of the present disclosure.

In some embodiments, the metrology system 100 includes an imaging sub-system 102 to generate an image of overlapping periodic features 104 on a sample 106 (e.g., a grating-over-grating structure, or the like) using zero-order double diffraction from the overlapping periodic features 104, where the overlapping periodic features 104 in different layers of the sample 106 are sufficiently close together to induce double diffraction of evanescent waves.

In this configuration, sample light 112 from the overlapping periodic features 104 (e.g., light emanating from the sample 106 at a reflection angle) includes zero-order overlapping periodic features 104, which is coded with various properties of the overlapping periodic features 104 including, but not limited to, overlay information associated with registration between associated periodic features, asymmetry information associated with any of the associated periodic features, or CD information associated with any of the periodic features. As a result, metrology measurements of such properties may be derived from an image of the overlapping periodic features 104 generated with this zero-order double diffraction.

The metrology system 100 may direct one or more illumination beams 108 from an illumination source 110 to the overlapping periodic features 104, collect sample light 112 including zero-order double diffraction, and generate an image of the overlapping periodic features 104 on a detector 114 based on the zero-order double diffraction. For example, FIG. 1A depicts imaging with two illumination beams 108 (e.g., two mutually coherent illumination beams 108). However, this is merely an illustration and not limiting on the scope of the present disclosure.

In some embodiments, the metrology system 100 further includes a controller 116 including one or more processors 118 configured to execute program instructions stored in memory 120 (e.g., a memory device). The processors 118 of the controller 116 may then execute program instructions causing the processors 118 to implement any of the various steps described in the present disclosure either directly or indirectly (e.g., by generating control signals to control components of the metrology system 100 and/or external components). For example, the processors 118 of the controller 116 may receive zero-order diffraction signals from the detector 114. As another example, the processors 118 of the controller 116 may generate one or more spatially-resolved metrology measurements of the sample 106 based on the zero-order diffraction signals. As another example, the processors 118 of the controller 116 may generate correctables to control, based on the spatially-resolved metrology measurements, one or more process tools such as, but not limited to, a lithography tool, an etching tool, or a polishing tool. Correctables may be generated to control one or more process tools in any combination of a feedback control loop or a feed-forward control loop. As an illustration, feedback correctables generated in response to metrology measurements on a sample 106 may control a process tool during the fabrication of additional samples in the same or different lots (e.g., in response to drifts of the process tools). As another illustration, feed-forward correctables generated in response metrology measurements on a sample 106 may be used to control a process tool during fabrication of additional features on the sample 106 in future process steps.

The one or more processors 118 of a controller 116 may include any processing element known in the art. In this sense, the one or more processors 118 may include any microprocessor-type device configured to execute algorithms and/or instructions. In some embodiments, the one or more processors 118 may consist of a desktop computer, mainframe computer system, workstation, image computer, parallel processor, or any other computer system (e.g., networked computer) configured to execute a program configured to operate the metrology system 100, as described throughout the present disclosure. It is further recognized that the term “processor” may be broadly defined to encompass any device having one or more processing elements, which execute program instructions from a non-transitory memory 120. Further, the steps described throughout the present disclosure may be carried out by a single controller 116 or, alternatively, multiple controllers. Additionally, the controller 116 may include one or more controllers housed in a common housing or within multiple housings. In this way, any controller or combination of controllers may be separately packaged as a module suitable for integration into metrology system 100.

The memory 120 may include any storage medium known in the art suitable for storing program instructions executable by the associated one or more processors 118. For example, the memory 120 may include a non-transitory memory medium. By way of another example, the memory 120 may include, but is not limited to, a read-only memory, a random-access memory, a magnetic or optical memory device (e.g., disk), a magnetic tape, a solid-state drive and the like. It is further noted that memory 120 may be housed in a common controller housing with the one or more processors 118. In some embodiments, the memory 120 may be located remotely with respect to the physical location of the one or more processors 118 and controller 116. For instance, the one or more processors 118 of controller 116 may access a remote memory (e.g., server), accessible through a network (e.g., internet, intranet and the like). Therefore, the above description should not be interpreted as a limitation on the present invention but merely an illustration.

Further, the metrology system 100 may be configurable to generate metrology measurements based on any number of metrology recipes, where a metrology recipe may define various imaging parameters used to generate measurement data and/or processing techniques to generate metrology measurements from measurement data. For example, a metrology recipe of may include parameters associated with one or more illumination beams 108 such as, but not limited to, a number of illumination beams 108, incidence angles (e.g., azimuth and/or polar incidence angles), polarization, phase characteristics, or wavelength. As another example, a metrology recipe may include parameters associated with sample light 112 used to generate an image such as, but not limited to, collection angles (e.g., to collect zero-order double diffraction), polarization, phase characteristics, or wavelength. As another example, a metrology recipe may include sampling characteristics such as, but not limited to, locations on a sample 106 to be measured (e.g., locations of dedicated overlay targets or device features to be characterized) or focus characteristics.

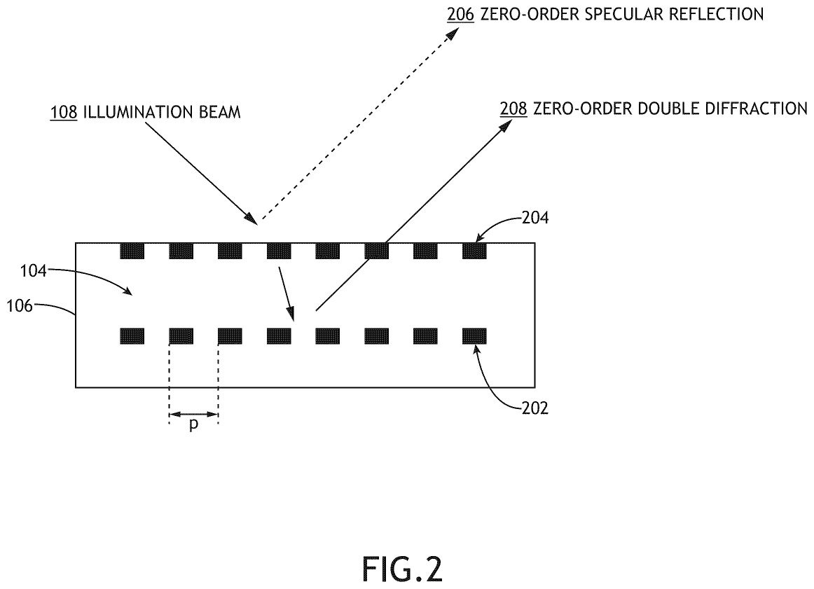

FIG. 2 illustrates the coding of metrology information into zero-order double-diffraction from overlapping periodic features 104, in accordance with one or more embodiments of the present disclosure.

In FIG. 2, overlapping periodic features 104 on a sample 106 are depicted conceptually as a grating-over-grating structure formed from first-layer periodic features 202 on a first layer of the sample 106 and second-layer periodic features 204 on a second layer of the sample 106, where the first-layer periodic features 202 and the second-layer periodic features 204 are at least partially overlapping. Further, the first-layer periodic features 202 and the second-layer periodic features 204 have a common pitch P. It is contemplated herein that such overlapping periodic features 104 may be naturally found in various device features (e.g., memory devices, logic devices, or the like) and/or in dedicated metrology targets such as, but not limited to, scatterometry overlay (SCOL) targets.

FIG. 2 depicts various zero-order light generated in response to an incident illumination beam 108 having an electric field Ei. For example, FIG. 2 depicts zero-order specular reflection 206 and zero-order double diffraction 208 associated with interaction of the illumination beam 108 with both the first-layer periodic features 202 and the second-layer periodic features 204 (e.g., double near-field diffraction associated with evanescent waves).

The zero-order double diffraction 208 may correspond to diffraction of opposing signs from the first-layer periodic features 202 and the second-layer periodic features 204. As an illustration, zero-order double diffraction 208 may be generated by +1 diffraction from the second-layer periodic features 204 and −1 diffraction from the first-layer periodic features 202 or −1 diffraction from the second-layer periodic features 204 and +1 diffraction from the first-layer periodic features 202. It is noted that the various arrows in FIG. 2 are intended solely to conceptually illustrate double diffraction, but do not represent precise optical paths.

It is contemplated herein that this zero-order double diffraction 208 may include “coded” information associated with various properties of the overlapping periodic features 104 such as, but not limited to, overlay information, CD information, or asymmetry information.

As an illustration considering an overlay measurement, the electric field of these combined signals may be characterized as:

$${E}_{0}^{r} {e}^{i δ} + {E}_{1}^{r} {e}^{i \frac{2 π}{P} OVL} = {E}_{0}^{r} ( cos ( δ ) + i sin ( δ ) ) + {E}_{1}^{r} ( cos ( \frac{2 π}{P} OVL ) + i sin ( \frac{2 π}{P} OVL ) ) = {E}_{0}^{r} cos ( δ ) + {E}_{1}^{r} cos ( \frac{2 π}{P} OVL ) + i ( {E}_{0}^{r} sin ( δ ) + {E}_{1}^{r} sin ( \frac{2 π}{P} OVL ) ) = J {e}^{i ϑ} \cdot {E}^{i} . \qquad ( 1 )$$

In Equation (1), OVL corresponds to overlay (e.g., physical registration between the first-layer periodic features 202 and the second-layer periodic features 204), P corresponds to a pitch of the first-layer periodic features 202 and the second-layer periodic features 204, and δ corresponds to a difference between first-order topographic phase and zero-order topographic phase of the second-layer periodic features 204. Put another way, δ corresponds to a difference between the electric field associated with zero-order specular reflection 206 and an electric field associated with zero-order double diffraction 208. This δ may include information about the second-layer periodic features 204 such as, but not limited to, critical dimension (CD) information or tilt information. Further, Je^{iθ} corresponds to a response function of the overlapping periodic features 104 (e.g., a Jones element, or the like).

A value of the overlay OVL may thus be extracted from a captured zero-order signal (e.g., as a metrology measurement). For example, an overlay measurement may be extracted based on fitting of an intensity of zero-order light captured by the detector 114, where the intensity is modeled based on an electric field such as, but not limited to, that described in Equation (1).

It is contemplated herein that local variations of the physical overlay (or other asymmetry-based metrology measurements) of the overlapping periodic features 104 may result in local variations of signal strength in an image of the overlapping periodic features 104 generated based on this zero-order light, even if the constituent features of the overlapping periodic features 104 (e.g., the first-layer periodic features 202 and the second-layer periodic features 204) are themselves not resolved by the imaging sub-system 102.

Although Equation (1) and the above description relate specifically to overlay, additional properties of the overlapping periodic features 104 or constituent features thereof (e.g., asymmetry properties, CD properties, or the like) may also be encoded into zero-order light (e.g., as represented by Je^{iθ} in Equation (1)).

In a general sense, the sensitivity of the intensity of zero-order light and thus the intensity or strength of zero-order signals associated with the overlapping periodic features 104 to any particular physical property of the overlapping periodic features 104 may depend on the polarization and phase of the illumination beam 108 and/or the zero-order light used for a measurement. In this way, ellipsometry techniques may be used to tune the sensitivity of a measurement to a particular parameter of interest. For example, the imaging sub-system 102 may include polarizers and/or phase-control optics (e.g., waveplates) in a pathway of illumination beams 108 and/or collected sample light 112 (e.g., collected zero-order light) to tune the sensitivity of a measurement to a particular parameter for a particular metrology measurement.

In some embodiments, the design of the sample 106 and/or the imaging sub-system 102 is designed to remove or reduce the zero-order specular reflection 206. For example, the imaging sub-system 102 may include crossed-polarizers in optical paths of the one or more illumination beams 108 and the zero-order double diffraction 208. As another example, the sample 106 may include a target designed to modify the polarization of zero-order specular reflection 206 with respect to higher-order light such that the zero-order specular reflection 206 may be filtered out with a polarizer in an imaging pathway. For example, the sample 106 may include a target as described in U.S. patent application Ser. No. 18/673,905 filed on May 24, 2024, which is incorporated herein by reference in its entirety.

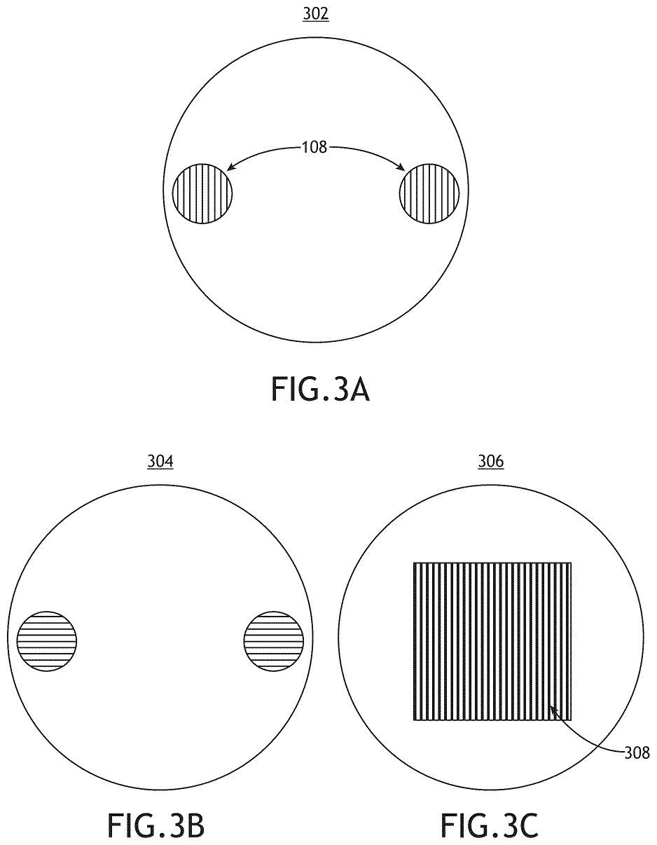

Referring now to FIGS. 1B and FIGS. 3A-3C, various imaging configurations are described, in accordance with one or more embodiments of the present disclosure.

FIG. 1B illustrates a simplified schematic of the imaging sub-system 102, in accordance with one or more embodiments of the present disclosure.

In some embodiments, the imaging sub-system 102 includes an illumination source 122 configured to generate at least one illumination beam 108. The illumination from the illumination source 122 may include one or more selected wavelengths of light including, but not limited to, ultraviolet (UV) radiation, visible radiation, or infrared (IR) radiation. For example, the may include one or more apertures at an illumination pupil plane to divide illumination from the illumination source 122 into one or more illumination beams 108 or illumination lobes. In this regard, the imaging sub-system 102 may provide dipole illumination, quadrature illumination, or the like. Further, the spatial profile of the one or more illumination beams 108 on the sample 106 may be controlled by a field-plane stop to have any selected spatial profile.

The illumination source 122 may include any type of illumination source suitable for providing at least one illumination beam 108. In some embodiments, the illumination source 122 is a laser source. For example, the illumination source 122 may include, but is not limited to, one or more narrowband laser sources, a broadband laser source, a supercontinuum laser source, a white light laser source, or the like. In some embodiments, the illumination source 122 includes a laser-sustained plasma (LSP) source. For example, the illumination source 122 may include, but is not limited to, a LSP lamp, a LSP bulb, or a LSP chamber suitable for containing one or more elements that, when excited by a laser source into a plasma state, may emit broadband illumination. In some embodiments, the illumination source 122 includes a lamp source. For example, the illumination source 122 may include, but is not limited to, an arc lamp, a discharge lamp, an electrode-less lamp, or the like.

In some embodiments, the imaging sub-system 102 directs the one or more illumination beams 108 to the sample 106 via an illumination pathway 124. The illumination pathway 124 may include one or more optical components suitable for modifying and/or conditioning the one or more illumination beams 108 as well as directing the one or more illumination beams 108 to the sample 106. In some embodiments, the illumination pathway 124 includes one or more illumination-pathway lenses 126 (e.g., to collimate the one or more illumination beams 108, to relay pupil and/or field planes, or the like). In some embodiments, the illumination pathway 124 includes one or more illumination-pathway optics 128 to shape or otherwise control the one or more illumination beams 108. For example, the illumination-pathway optics 128 may include, but are not limited to, one or more polarizers, one or more phase-control optics (e.g., waveplates), one or more field stops, one or more pupil stops, one or more one or more filters (e.g., spatial and/or spectral filters), one or more beam splitters, one or more diffusers, one or more homogenizers, one or more apodizers, one or more beam shapers, or one or more mirrors (e.g., static mirrors, translatable mirrors, scanning mirrors, or the like).

In some embodiments, the imaging sub-system 102 includes an objective lens 130 to focus the one or more illumination beams 108 onto the sample 106 (e.g., onto the overlapping periodic features 104).

In some embodiments, the sample 106 is disposed on a sample stage 132 suitable for securing the sample 106 and further configured to position the sample 106 with respect to the imaging sub-system 102.

In some embodiments, the imaging sub-system 102 images the sample 106 onto at least one detector 114 through a collection pathway 134 based on zero-order light including at least zero-order double diffraction 208. For example, the collection pathway 134 may include optics to collect sample light 112 including at least zero-order double diffraction 208 from overlapping periodic features 104 and form an image on the detector 114 based on this zero-order double diffraction 208. In this way, the detector 114 may generate zero-order double diffraction signals associated with the overlapping periodic features 104 based on portions of an image of the sample 106 including the overlapping periodic features 104. As is described throughout the present disclosure, spatial variations of these zero-order double diffraction signals across portions of the image associated with the overlapping periodic features 104 may be the basis for spatially-resolved metrology measurements of the overlapping periodic features 104.

The collection pathway 134 may include one or more optical elements suitable for modifying and/or conditioning the sample light 112 from the sample 106. In some embodiments, the collection pathway 134 includes one or more collection-pathway lenses 136 (e.g., to collimate the sample light 112, to relay pupil and/or field planes, or the like), which may include, but is not required to include, the objective lens 130. In some embodiments, the collection pathway 134 includes one or more collection-pathway optics 138 to shape or otherwise control the sample light 112. For example, the collection-pathway optics 138 may include, but are not limited to, one or more polarizers, one or more phase-control optics (e.g., waveplates), one or more field stops, one or more pupil stops, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In some embodiments, the illumination-pathway optics 128 and/or the collection-pathway optics 138 include ellipsometry optics suitable for providing ellipsometry measurements based on the zero-order double diffraction signals. For example, the illumination-pathway optics 128 may include at least one of a polarizer or a waveplate to manipulate a polarization and/or phase of the one or more illumination beams 108. As another example, the collection-pathway optics 138 may include at least one of a polarizer or a waveplate to manipulate a polarization and/or phase of the one or more zero-order double diffraction 208. It is contemplated herein that different combinations of such ellipsometry optics may adjust the sensitivity of the zero-order double diffraction signals to different Mueller matrix elements associated with the overlapping periodic features 104, which may be the basis for different metrology measurements. Accordingly, the metrology system 100 may generate zero-order diffraction signals with one or more configurations of the ellipsometry optics and generate one or more metrology measurements based on these zero-order diffraction signals generated with the different configurations of the ellipsometry optics.

The detector 114 may be placed at field plane conjugate to the sample 106. Further, the detector 114 may generally include any type of sensor suitable for imaging the sample 106. In some embodiments, the detector 114 is suitable for characterizing a static sample such as, but not limited to, a charge-coupled device (CCD) or a complementary metal-oxide semiconductor (CMOS) device. In this regard, the detector 114 may generate a two-dimensional image in a single measurement. In some embodiments, the detector 114 is suitable for characterizing a moving sample (e.g., a scanned sample). In this regard, the imaging sub-system 102 may operate in a scanning mode in which the sample 106 is scanned with respect to a measurement field during a measurement. For example, the detector 114 may include a 2D pixel array with a capture time and/or a refresh rate sufficient to capture one or more images during a scan within selected image tolerances (e.g., image blur, contrast, sharpness, or the like). By way of another example, the detector 114 may include a line-scan detector to continuously generate an image one line of pixels at a time. By way of another example, the detector 114 may include a time-delay integration (TDI) detector.

The illumination pathway 124 and the collection pathway 134 of the imaging sub-system 102 may be oriented in a wide range of configurations. For example, as illustrated in FIG. 1B, the imaging sub-system 102 may include a beamsplitter 140 oriented such that a common objective lens 130 may simultaneously direct the one or more illumination beams 108 to the sample 106 and collect light from the sample 106. For example, the illumination pathway 124 and the collection pathway 134 may contain non-overlapping optical paths and/or separate optical components.

Various aspects of imaging with zero-order double diffraction 208 are now described in greater detail, in accordance with one or more embodiments of the present disclosure. As described previously herein, the constituent features (e.g., the first-layer periodic features 202 and/or the second-layer periodic features 204) may not be resolved in an image generated with zero-order light including the zero-order double diffraction 208. However, the signal strength of the image may be related to properties of the overlapping periodic features 104 such that local variations of these properties may result in local variations of the signal strength of the image.

In some embodiments, the imaging sub-system 102 directs two mutually-coherent illumination beams 108 (e.g., temporally-coherent illumination beams 108) to overlapping periodic features 104 on a sample 106 at opposing azimuth incidence angles, collects at least zero-order double diffraction 208 associated with the mutually-coherent illumination beams 108, and generates an image of the overlapping periodic features 104 based on interference of the associated zero-order double diffraction 208. In this configuration, the image generated by a detector 114 may include a sinusoidal pattern associated with the interference, where an amplitude of the sinusoidal pattern is correlated with one more properties of the overlapping periodic features 104. It is contemplated herein that such a configuration may provide measurements with a high signal to noise ratio (SNR). In particular, the sinusoidal pattern that is correlated with a measurement of interest may be isolated using signal processing techniques such as, but not limited to, spatial Fourier Transform techniques.

Mutually-coherent illumination beams 108 may be generated using any suitable technique. For example, mutually-coherent illumination beams 108 may be generated by placing an apodizer with two apertures in an illumination pupil plane and illuminating the apodizer with coherent illumination. As another example, coherent illumination may be split and directed to different locations of an illumination pupil plane. Further, mutually-coherent illumination beams 108 may have any bandwidth sufficient to maintain mutual coherence and the generation of the interference of the associated zero-order double diffraction 208.

FIG. 1C illustrates a simplified schematic view of a configuration of the imaging sub-system 102 providing imaging based on zero-order light from a pair of mutually-coherent illumination beams 108, in accordance with one or more embodiments of the present disclosure.

FIG. 1C is substantially similar to FIG. 1B, except that FIG. 1C includes a particular configuration of two illumination beams 108. Accordingly, the description of FIG. 1B may be extended to FIG. 1C.

In FIG. 1C, a pair of mutually-coherent illumination beams 108 are directed to different locations of a beamsplitter 140 and then to the objective lens 130. When the objective lens 130 is centered with respect to the illumination beams 108, such a configuration directs the illumination beams 108 to the sample 106 with opposing azimuth incidence angles and equal polar incidence angles. Differences in optical path lengths in the beamsplitter 140 result in differences in optical phase of the illumination beams 108, which is represented in FIG. 1C as phases of ±φ.

Zero-order light including the zero-order double diffraction 208 from each of the illumination beams 108 is then collected by the objective lens 130 (e.g., along optical paths of the opposing illumination beams 108) and directed back through the beamsplitter 140, where the differences in optical phase are removed as shown in FIG. 1C. One or more collection-pathway lenses 136 then interferes the zero-order double diffraction 208 on the detector 114 to generate an image of the overlapping periodic features 104 that includes an interference pattern.

FIG. 1C further depicts ellipsometry optics 142 in the form of illumination-pathway optics 128 including a polarizer (P) and a waveplate (WP), along with collection-pathway optics 138 including an analyzer (A) (e.g., another polarizer) and another waveplate (WP). Such a configuration may enable tuning the sensitivity of the amplitude of the sinusoidal pattern in the image to selected properties of the overlapping periodic features 104 using ellipsometry techniques.

FIGS. 3A-3C depict various aspects of imaging based on zero-order double diffraction 208 from a pair of mutually-coherent illumination beams 108, in accordance with one or more embodiments of the present disclosure. In this way, FIGS. 3A-3C may correspond to imaging using the configuration in FIG. 1C, but are not limited to this configuration.

FIG. 3A illustrates two mutually-coherent illumination beams 108 at opposing portions of an illumination pupil 302, in accordance with one or more embodiments of the present disclosure. In FIG. 3A, the vertical lines associated with the illumination beams 108 represent polarization rather than intensity (e.g., the illumination beams 108 may have uniform intensity profiles in the illumination pupil 302). For example, the polarizer (P) in the illumination-pathway optics 128 may be oriented to polarize the illumination beams 108 along the direction shown.

FIG. 3B illustrates a collection pupil 304 depicting zero-order double diffraction 208 from the overlapping periodic features 104 associated with the pair of mutually-coherent illumination beams 108 oriented as shown in FIG. 3A, in accordance with one or more embodiments of the present disclosure. The horizontal lines depicted in FIG. 3C represent polarization rather than intensity. For example, the analyzer (A) in the collection-pathway optics 138 may be oriented orthogonal to the polarizer (P) to provide measurement of cross-polarized light. Such a configuration may be suitable for, but not limited to, overlay measurements. In a general sense, the illumination-pathway optics 128 and collection-pathway optics 138 may be configured in any way suitable for providing a sensitivity to a selected property of the overlapping periodic features 104.

FIG. 3C illustrates an image 306 of overlapping periodic features 104 generated based on the collected zero-order double diffraction 208, in accordance with one or more embodiments of the present disclosure. In FIG. 3C, the pair of mutually-coherent illumination beams 108 fully illuminate the overlapping periodic features 104 (or a region of interest thereon). Further, the overlapping periodic features 104 are unresolved and the zero-order double diffraction signals in the image 306 includes an interference pattern with fringes 308 associated with interference of the zero-order double diffraction 208 from the two illumination beams 108. As described previously herein, localized variations of properties of the overlapping periodic features 104 may manifest as localized variations of the amplitude of the fringes of the interference pattern in the image 306. In this way, spatially-resolved metrology measurements may be generated from the zero-order double diffraction signals in the image 306.

As an illustration, Equations (2)-(6) depict the relationship between overlay of first-layer periodic features 202 and second-layer periodic features 204 image signal strength (e.g., image intensity) for an image 306 generated with zero-order double diffraction 208 from mutually-coherent illumination beams 108.

A plane wave (e.g., an illumination beam 108) incident on overlapping periodic features 104 at an angle θ may provide zero-order double diffraction 208 that may be described as:

$$E = {e}^{ikxsin ( θ )} \cdot {\sum }_{n \neq 0} {f}_{n} {g}_{- n} {e}^{i \frac{2 π n}{P} OVL} \qquad ( 2 )$$

where fₙ and gₙ are amplitudes of an n^{th} diffraction order, k=2π/λ, and λ corresponds to wavelength of the plane wave. In this way, Equation (2) extends the description of Equation (1) to include multiple potential formations of zero-order double diffraction 208 (e.g., zero-order double diffraction 208 from +/−1 diffraction orders, +/−2 diffraction orders, and the like).

However, it is contemplated herein that the amplitude of zero-order double diffraction 208 strongly diminishes for n≥2. Accordingly, zero-order double diffraction 208 may be written more simply as:

$$E = {e}^{ikxsin ( θ )} \cdot ( {f}_{1} {g}_{- 1} {e}^{i \frac{2 π}{P} OVL} + {f}_{- 1} {g}_{1} {e}^{- i \frac{2 π}{P} OVL} ) \qquad ( 3 )$$

For a configuration with two mutually-coherent illumination beams 108 at opposing incidence angles ±θ, one can write a combined electric field at the detector 114 as:

$$E = {e}^{ikxsin ( θ )} \cdot ( {f}_{1} {g}_{- 1} {e}^{i \frac{2 π}{P} OVL} + {f}_{- 1} {g}_{1} {e}^{- i \frac{2 π}{P} OVL} ) + {e}^{ikxsin ( θ )} \cdot ( {f}_{- 1} {g}_{1} {e}^{i \frac{2 π}{P} OVL} + {f}_{1} {g}_{- 1} {e}^{- i \frac{2 π}{P} OVL} ) \qquad ( 4 )$$

where a symmetric property of f₁(θ)=f₋₁(−θ) and g₁(θ)=g₋₁(−θ) is applied.

An intensity on the detector 114 may then be written as:

$$I = {\vert {e}^{ikxsin θ} \cdot ( {A}_{1} {e}^{i \frac{2 π}{P} OVL} + {A}_{- 1} {e}^{- i \frac{2 π}{P} OVL} ) + {e}^{- ikxsin θ} \cdot ( {A}_{- 1} {e}^{i \frac{2 π}{P} OVL} + {A}_{1} {e}^{- i \frac{2 π}{P} OVL} ) \vert}^{2} \qquad ( 5 )$$

$$or$$

$${I = 2 {\vert {A}_{1} \vert}^{2} + 2 \vert {A}_{- 1} \vert}^{2} + cos ( \frac{4 π}{P} OVL ) ( {A}_{- 1} {A}_{1}^{*} + {A}_{1} {A}_{- 1}^{*} ) + 4 cos ( 2 kx sin θ ) ( {A}_{- 1} {A}_{1}^{*} + {A}_{1} {A}_{- 1}^{*} ) + 4 ( {\vert {A}_{1} \vert}^{2} + {\vert {A}_{- 1} \vert}^{2} ) cos ( \frac{4 π}{P} OVL ) cos ( 2 kx sin θ ) + 4 ( {\vert {A}_{1} \vert}^{2} - {\vert {A}_{- 1} \vert}^{2} ) sin ( \frac{4 π}{P} OVL ) sin ( 2 kx sin θ ) , \qquad ( 6 )$$

where A₁=f₁g₋₁ and A₋₁=f₋₁g₁.

Equation (6) demonstrates that the amplitude of sinusoidal variations in an image is correlated to overlay between the first-layer periodic features 202 and the second-layer periodic features 204. Further, the term

$$4 ( {\vert {A}_{1} \vert}^{2} - {\vert {A}_{- 1} \vert}^{2} sin ( \frac{4 π}{P} ) OVL ) sin ( 2 kx sin θ )$$

may vanish as |A₁|²⇒|A₋₁|² such that the sinusoidal oscillations in the image may be dominated by the term

$$4 ( {\vert {A}_{1} \vert}^{2} + {\vert {A}_{- 1} \vert}^{2} cos ( \frac{4 π}{P} ) OVL ) cos ( 2 kx sin θ ) ,$$

which has an amplitude that depends on overlay as

$$4 ( {\vert {A}_{1} \vert}^{2} + {\vert {A}_{- 1} \vert}^{2} cos ( \frac{4 π}{P} ) OVL ) .$$

In some embodiments, a dedicated metrology target with overlapping periodic features 104 includes a designed (e.g., intentional) overlay offset between first-layer periodic features 202 and second-layer periodic features 204. For example, an intentional overlay of a quarter of the pitch

$$OVL = \frac{P}{4}$$

may provide high signal strength. Other intentional overlay offset values may be chosen to balance signal strength and sensitivity to localized overlay deviations.

In some embodiments, the imaging sub-system 102 directs a single illumination beam 108 to overlapping periodic features 104 on a sample 106 and generates zero-order double diffraction signals (e.g., one or more images based on collected zero-order double diffraction 208) from this single illumination beam 108. In this configuration, the signal strength of the image may be directly correlated to one or more properties of the overlapping periodic features 104 (e.g., overlay, asymmetry, CD, or the like). Further, overlay may be determined based on multiple zero-order double diffraction signals with different imaging configurations (e.g., different configurations of the ellipsometry optics 142).

FIG. 1D illustrates a simplified schematic view of a first configuration of the imaging sub-system 102 providing imaging based on zero-order light from a single illumination beam 108, in accordance with one or more embodiments of the present disclosure. FIG. 1D is similar to FIG. 1C modified to provide imaging with a single imaging sub-system 102 such that the description of elements in FIG. 1C may extend to FIG. 1D. In FIG. 1D, multiple images of the sample 106 are generated at different configurations of the wavelength and/or angle (e.g., illumination pupil position) of the single illumination beam 108. In this configuration, an illumination field plane 144 (e.g., accessible through illumination-pathway lenses 126) includes an open aperture 146 such that a full image of the overlapping periodic features 104 is generated on the detector 114 for each configuration. In some embodiments, multiple zero-order double diffraction signals are generated based on multiple wavelengths, where spatially-resolved metrology measurements are generated based on these multiple zero-order double diffraction signals. For example, the single illumination beam 108 may be shaped to have a beam profile that covers a region of interest of the overlapping periodic features 104 and the wavelength of the single illumination beam 108 may be stepped through a range to provide separate zero-order double diffraction signals at separate wavelengths. The wavelength tuning may be implemented using any technique including, but not limited to, modifying the illumination source 110 to directly produce different wavelengths or using one or more narrowband filters to select desired wavelengths from broadband light generated by the illumination source 110.

FIG. 1E illustrates a simplified schematic view of a first configuration of the imaging sub-system 102 providing imaging based on zero-order light from a single illumination beam 108, in accordance with one or more embodiments of the present disclosure. FIG. 1E is similar to FIG. 1E except that the illumination beam 108 is shaped as a slit smaller than a region of interest of the overlapping periodic features 104, which many be sequentially stepped across the region of interest to provide multiple sets of zero-order double diffraction signals. For example, FIG. 1E depicts a configuration where the illumination field plane 144 includes an adjustable slit aperture 148 to illuminate an adjustable slice of the overlapping periodic features 104 (e.g., an image of the slit aperture 148). The associated sample light 112 is then directed to a diffraction grating 150 prior to the detector 114 to generate a wavelength-resolved image of the illuminated slice of the overlapping periodic features 104, where wavelength coordinate and slit coordinate directions are schematically shown in FIG. 1E. Further, multiple zero-order double diffraction signals (e.g., multiple images generated with zero-order double diffraction 208) are generated for different positions of the slit aperture 148 associated with different portions of the overlapping periodic features 104. For example, the overlapping periodic features 104 may be translated with respect to the illumination beam 108 along a direction orthogonal to a long axis of the project slit aperture 148 such that multiple sets of zero-order double diffraction signals may be generated for the different positions. Spatially-resolved metrology measurements may then be generated based on these multiple zero-order double diffraction signals.

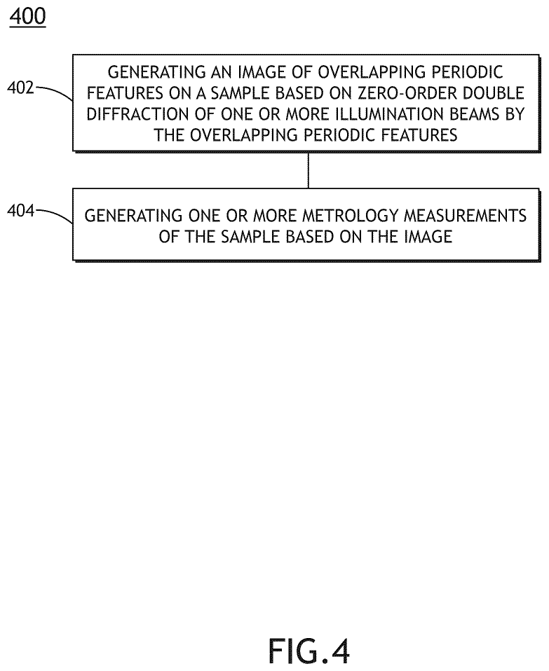

Referring now to FIG. 4, FIG. 4 illustrates a flow diagram illustrating steps performed in a metrology method 400, in accordance with one or more embodiments of the present disclosure. The embodiments and enabling technologies described previously herein in the context of the metrology system 100 should be interpreted to extend to the method 400. For example, the processors 118 of the controller 116 may be configured to execute program instructions stored on the memory 120, where the program instructions cause the processors 118 to perform any of the steps of the method 400 either directly or indirectly (e.g., by generating control signals to direct another component to perform an action). However, the method 400 is not limited to the architecture of the metrology system 100.

The method 400 may include a step 402 of generating zero-order double diffraction signals associated with overlapping periodic features 104 on a sample 106 based on zero-order double diffraction 208 of one or more illumination beams 108 by the overlapping periodic features 104. For example, the step 402 may include imaging the sample based on the zero-order double diffraction 208, where zero-order double diffraction signals are generated in portions of the image associated with the overlapping periodic features 104. The overlapping periodic features 104 may be unresolved in the image. The method 400 may also include a step 404 of generating one or more spatially-resolved metrology measurements of the sample 106 based on the zero-order double diffraction signals.

In some embodiments, the method may include adjusting polarization and/or phase of the one or more illumination beams 108 as well as the zero-order double diffraction 208 may be tuned (e.g., through any combination of polarizers and waveplates) for a particular metrology measurement of a selected property of the overlapping periodic features 104. For example, the illumination beams 108 may be directed to the overlapping periodic features 104 with one polarization, while the zero-order double diffraction 208 used to generate the image may have an orthogonal (e.g., crossed polarization). More generally, ellipsometry optics 142 such as, but not limited to, polarizers or waveplates may be used to modify the polarization and/or phase of any combination of the one or more illumination beams 108 or the zero-order double diffraction 208. In this way, the step 402 may include generating multiple zero-order double diffraction signals associated with different combinations of the ellipsometry optics 142, and the step 404 may include generating multiple spatially-resolved metrology measurements based on the different zero-order double diffraction signals. It is contemplated herein that such a technique enables the use of ellipsometric techniques to generate spatially-resolved metrology measurements of a wide range of properties including, but not limited to, Mueller matrix element measurements, overlay measurements, tilt measurements, or CD measurements.

In some embodiments, the step 402 may include directing two temporally coherent (e.g., mutually coherent) illumination beams 108 to the sample 106 at opposing azimuth angles and generating the image based on interference of zero-order light (e.g., including zero-order double diffraction 208) of the two temporally coherent illumination beams 108 by the overlapping periodic features 104. In this configuration, a metrology measurement may be generated based on an amplitude of interference fringes associated with interference of the zero-order double diffraction 208 from the two temporally coherent illumination beams 108.

In some embodiments, the step 402 may include directing a single illumination beam 108 to the overlapping periodic features 104. In this configuration, a metrology measurement may be generated based on an intensity of the image.

In either case, localized variations of properties of the overlapping periodic features 104 may be measured based on localized variations in the associated image.

In some embodiments, the method 400 further includes a step of generating correctables for one or more process tools based on the one or more metrology measurements. For example, the correctables based on one or more metrology measurements may be used to control a fabrication tool using any combination of feed-forward or feedback control techniques. As an illustration, feedback control may be used to compensate for deviations of a fabrication tool for various samples within a lot or series of lots. As another illustration, feed-forward control may be used to compensate for deviations measured at one process step for a sample or series of samples when performing a subsequent process step. Any type of fabrication tool may be controlled such as, but not limited to, a lithography tool (e.g., a scanner, a stepper, or the like), an etching tool, or a polishing tool.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
an illumination source configured to generate one or more illumination beams;
an imaging sub-system comprising:
one or more lenses configured to image a sample onto a detector located in a field plane conjugate to the sample, wherein the sample includes overlapping periodic features on two sample layers, wherein the overlapping periodic features on the two sample layers have a common pitch, wherein the detector generates zero-order double diffraction signals associated with zero-order double diffraction of the one or more illumination beams by the overlapping periodic features; and
one or more ellipsometry optics including at least one of a polarizer or a waveplate in an optical path associated with at least one of the one or more illumination beams or the zero-order double diffraction; and
a controller including one or more processors configured to execute program instructions causing the one or more processors to implement a metrology recipe by:
receiving the zero-order double diffraction signals associated with the overlapping periodic features from the detector and generated with one or more configurations of the one or more ellipsometry optics, wherein constituent features of the overlapping periodic features are unresolved in the zero-order double diffraction signals; and
generating one or more spatially-resolved metrology measurements of the sample based on spatial variations of the zero-order double diffraction signals generated with the one or more configurations of the one or more ellipsometry optics.

2. The metrology system of claim 1, wherein the zero-order double diffraction corresponds to double near-field diffraction from the overlapping periodic features.

3. The metrology system of claim 1, wherein the one or more spatially-resolved metrology measurements comprise:
at least one of an overlay measurement, an asymmetry measurement, or a critical dimension measurement.

4. The metrology system of claim 1, wherein the one or more spatially-resolved metrology measurements correspond to spatially-resolved measurements of one or more Mueller matrix elements.

5. The metrology system of claim 1, wherein the one or more illumination beams from the illumination source comprise two temporally coherent illumination beams, wherein the imaging sub-system directs the two temporally coherent illumination beams to the overlapping periodic features at opposing azimuth incidence angles, wherein the imaging sub-system images the overlapping periodic features on the detector based on interference between the zero-order double diffraction of the two temporally coherent illumination beams.

6. The metrology system of claim 5, wherein generating the one or more spatially-resolved metrology measurements of the sample based on the zero-order double diffraction signals comprises:
generating the one or more spatially-resolved metrology measurements based on an amplitude of sinusoidal variations in the zero-order double diffraction signals associated with the interference of the zero-order double diffraction of the two temporally coherent illumination beams.

7. The metrology system of claim 6, wherein the one or more spatially-resolved metrology measurements comprise an overlay measurement.

8. The metrology system of claim 7, wherein the overlapping periodic features include first-layer features and second-layer features, wherein the first-layer features and the second-layer features have the common pitch, wherein the first-layer features and the second-layer features have a designed overlay offset equal to a quarter of the common pitch.

9. The metrology system of claim 1, wherein the one or more illumination beams from the illumination source comprise a single illumination beam.

10. The metrology system of claim 9, wherein generating the one or more spatially-resolved metrology measurements of the sample based on the zero-order double diffraction signals comprises:
generating the one or more spatially-resolved metrology measurements of the sample based on the spatial variations of the zero-order double diffraction signals.

11. The metrology system of claim 9, wherein the zero-order double diffraction signals associated with the overlapping periodic features from the detector and generated with the one or more configurations of the one or more ellipsometry optics comprise:
two or more sets of zero-order double diffraction signals generated with different wavelengths of the single illumination beam, wherein the single illumination beam illuminates a region of interest of the overlapping periodic features.

12. The metrology system of claim 9, wherein the single illumination beam is shaped as a slit having dimensions smaller than a region of interest of the overlapping periodic features, wherein the zero-order double diffraction signals associated with the overlapping periodic features from the detector and generated with the one or more configurations of the one or more ellipsometry optics comprise:
two or more sets of zero-order double diffraction signals generated with different positions of the slit across the region of interest.

13. The metrology system of claim 1, wherein the overlapping periodic features comprise:
device features within a die on the sample.

14. The metrology system of claim 13, wherein the overlapping periodic features are associated with at least one of a memory device or a logic device.

15. The metrology system of claim 1, wherein the overlapping periodic features are associated with a metrology target.

16. The metrology system of claim 1, wherein the program instructions further cause the one or more processors to generate correctables for one or more fabrication tools based on the one or more spatially-resolved metrology measurements.

17. A metrology system comprising:
a controller including one or more processors configured to execute program instructions causing the one or more processors to implement a metrology recipe by:
receiving zero-order double diffraction signals associated with overlapping periodic features on two sample layers of a sample from a detector, wherein the overlapping periodic features on the two sample layers have a common pitch, wherein the zero-order double diffraction signals are based on zero-order double diffraction of one or more illumination beams by the overlapping periodic features, wherein the zero-order double diffraction signals are associated with one or more configurations of ellipsometry optics including at least one of a polarizer or a waveplate in an optical path associated with at least one of the one or more illumination beams or the zero-order double diffraction; and
generating one or more spatially-resolved metrology measurements of the sample based on the zero-order double diffraction signals.

18. The metrology system of claim 17, wherein the zero-order double diffraction corresponds to double near-field diffraction from the overlapping periodic features.

19. The metrology system of claim 17, wherein the one or more spatially-resolved metrology measurements comprise:
at least one of an overlay measurement, an asymmetry measurement, or a critical dimension measurement.

20. The metrology system of claim 17, wherein the one or more spatially-resolved metrology measurements correspond to spatially-resolved measurements of one or more Mueller matrix elements.

21. The metrology system of claim 17, wherein the one or more illumination beams comprise two temporally coherent illumination beams, wherein the two temporally coherent illumination beams are directed to the overlapping periodic features at opposing azimuth incidence angles, wherein the zero-order double diffraction signals are based on interference between the zero-order double diffraction of the two temporally coherent illumination beams.

22. The metrology system of claim 21, wherein generating the one or more spatially-resolved metrology measurements of the sample based on the zero-order double diffraction signals comprises:
generating the one or more spatially-resolved metrology measurements based on an amplitude of sinusoidal variations in the zero-order double diffraction signals associated with the interference of the zero-order double diffraction of the two temporally coherent illumination beams.

23. The metrology system of claim 22, wherein the one or more spatially-resolved metrology measurements comprise an overlay measurement.

24. The metrology system of claim 23, wherein the overlapping periodic features include first-layer features and second-layer features, wherein the first-layer features and the second-layer features have the common pitch, wherein the first-layer features and the second-layer features have a designed overlay offset equal to a quarter of the common pitch.

25. The metrology system of claim 17, wherein the one or more illumination beams comprise a single illumination beam.

26. The metrology system of claim 25, wherein generating the one or more spatially-resolved metrology measurements of the sample based on the zero-order double diffraction signals comprises:
generating the one or more spatially-resolved metrology measurements of the sample based on intensity in the zero-order double diffraction signals.

27. The metrology system of claim 25, wherein the zero-order double diffraction signals associated with the overlapping periodic features from the detector and generated with the one or more configurations of the ellipsometry optics comprise:
two or more sets of zero-order double diffraction signals generated with different wavelengths of the single illumination beam, wherein the single illumination beam illuminates a region of interest of the overlapping periodic features.

28. The metrology system of claim 25, wherein the single illumination beam is shaped as a slit having dimensions smaller than a region of interest of the overlapping periodic features, wherein the zero-order double diffraction signals associated with the overlapping periodic features from the detector and generated with the one or more configurations of the ellipsometry optics comprise:
two or more sets of zero-order double diffraction signals generated with different positions of the slit across the region of interest.

29. The metrology system of claim 25, wherein generating the one or more spatially-resolved metrology measurements of the sample based on the zero-order double diffraction signals comprises:
generating the one or more spatially-resolved metrology measurements of the sample based on spatial variations of intensity in the zero-order double diffraction signals.

30. The metrology system of claim 17, wherein the overlapping periodic features comprise:
device features within a die on the sample.

31. The metrology system of claim 30, wherein the overlapping periodic features are associated with at least one of a memory device or a logic device.

32. The metrology system of claim 17, wherein the overlapping periodic features are associated with a metrology target.

33. The metrology system of claim 17, wherein the program instructions further cause the one or more processors to generate correctables for one or more fabrication tools based on the one or more spatially-resolved metrology measurements.

34. A metrology system comprising:
generating zero-order double diffraction signals associated with overlapping periodic features on two sample layers of a sample based on zero-order double diffraction of one or more illumination beams by the overlapping periodic features, wherein the overlapping periodic features on the two sample layers have a common pitch, wherein the zero-order double diffraction signals are associated with one or more configurations of ellipsometry optics including at least one of a polarizer or a waveplate in an optical path associated with at least one of the one or more illumination beams or the zero-order double diffraction; and
generating one or more spatially-resolved metrology measurements of the sample based on the zero-order double diffraction signals.

35. The metrology system of claim 34, wherein generating the one or more spatially-resolved metrology measurements of the sample based on the zero-order double diffraction signals comprises:
generating the one or more spatially-resolved metrology measurements of the overlapping periodic features.

36. The metrology system of claim 34, wherein generating the one or more spatially-resolved metrology measurements of the sample based on the zero-order double diffraction signals comprises:
generating at least one of an overlay measurement, an asymmetry measurement, or a critical dimension measurement.

37. The metrology system of claim 34, wherein generating the one or more spatially-resolved metrology measurements of the sample based on the zero-order double diffraction signals comprises:
generating a measurement of at least one Mueller matrix element.

38. The metrology system of claim 34, wherein the one or more illumination beams comprise two temporally coherent illumination beams, wherein generating the zero-order double diffraction signals associated with the overlapping periodic features on the two sample layers of the sample based on the zero-order double diffraction of the one or more illumination beams by the overlapping periodic features comprises:
directing the two temporally coherent illumination beams to the overlapping periodic features at opposing azimuth incidence angles; and
imaging the overlapping periodic features based on interference between the zero-order double diffraction of the two temporally coherent illumination beams.

39. The metrology system of claim 34, further comprising:
generating one or more correctables for a fabrication tool based on the one or more spatially-resolved metrology measurements.
